(19) United States
(12) Patent Application Publication
(10) Pub. No.: US 2015/0053456 A1
(43) Pub. Date: Feb. 26, 2015

(54) PRINTED CIRCUIT BOARD AND MANUFACTURING METHOD THEREOF

(71) Applicant: SAMSUNG ELECTRO-MECHANICS CO., LTD., SUWON (KR)

(72) Inventors: CHANG BO LEE, SUWON (KR); MYEONG HO HONG, CHANGWON (KR); DAE JO HONG, HWASUNG (KR); YOUNG KYU LIM, BUSAN (KR)

(73) Assignee: SAMSUNG ELECTRO-MECHANICS CO., LTD., SUWON (KR)

(21) Appl. No.: 14/134,534

(22) Filed: Dec. 19, 2013

(30) Foreign Application Priority Data
Aug. 26, 2013 (KR) 10-2013-0101241

(51) Int. Cl. H05K 1/11; H05K 3/22

(52) U.S. Cl. CPC H05K 1/119; H05K 3/22
USPC 174/250; 430/312

(57) ABSTRACT

A printed circuit board and a manufacturing method thereof. The manufacturing method of the printed circuit board includes: coating a first solder resist on an upper surface of a substrate having a circuit pattern formed thereon; removing the first solder resist in the remaining portion except a first specific area by performing primary development after exposing the substrate coated with the first solder resist; coating a second solder resist, which has different properties from the first solder resist, on the upper surface of the substrate having the first solder resist remaining in the first specific area; and removing the second solder resist in the remaining portion except a second specific area by performing secondary development after exposing the substrate coated with the second solder resist.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2013-0101241, entitled filed Aug. 26, 2013, which is hereby incorporated by reference in its entirety into this application.”

### BACKGROUND OF THE INVENTION

1. Field of the Invention

The present invention relates to a printed circuit board and a manufacturing method thereof, and more particularly, to a printed circuit board and a manufacturing method thereof that can improve reliability of a thin solder resist area.

2. Description of the Related Art

In manufacturing a printed circuit board (PCB), opening of solder resist in a solder resist process is an operation required for the role as a passage for electrical connection with a chip. In recent times, 3D packaging is in the limelight and multi-layered solder resist is required to satisfy the corresponding technical requirements. In particular, 2-step solder resist is frequently required for a thermal compression flip chip (TCFC) PCB having a peripheral bump.

This is because the thickness of the solder resist should be relatively small to be bonded to a Cu pillar on the side surface of a chip in a flip chip area and the thickness of the solder resist should be relatively large to be bonded to a chip or an interposer positioned above the chip in a package-on-package (PoP) pad area at a minimum pitch. Further, a step due to the thickness of the solder resist also performs a role of an underfill flow barrier during the TCFC packaging of the flip chip (FC) area. However, since the thin area is relatively weak in terms of reliability due to the influence of moisture absorption etc, a complement to it is needed.

In general, a 2-step solder resist process forms a PoP area thick and an FC area thin. A peripheral bump area is usually completely opened. In this structure, solder resist in a thin layer and solder resist in a thick layer usually have the same properties. Here, the properties mean bulk properties of a material such as coefficient of thermal expansion (CTE) and moisture absorption rate and surface properties such as surface roughness, surface energy, and wettability at the same time. It is apparent that the thin solder resist area is relatively weaker than the thick solder resist area in the severe reliability conditions.

### RELATED ART DOCUMENT

### Patent Document

Patent Document 1: Korean Patent Publication No. 10-2012-0034530
Patent Document 2: Japanese Patent Publication No. 2012-169598

### SUMMARY OF THE INVENTION

The present invention has been invented in order to overcome the above-described problems and it is, therefore, an object of the present invention to provide a printed circuit board and a manufacturing method thereof that can improve reliability of a thin solder resist area by differentiating properties of the thin solder resist area and the thick solder resist area in a multilayer solder resist structure.

In accordance with an embodiment of the present invention to achieve the object, there is provided a printed circuit board including: a substrate for forming a base of the printed circuit board; a circuit pattern formed on the substrate in a predetermined pattern; a first solder resist formed in a first specific area on the substrate having the circuit pattern formed thereon; and a second solder resist formed in a second specific area on the substrate having the circuit pattern formed thereon to be stepped from the first solder resist and having different properties from the first solder resist.

Here, the first specific area may be a flip chip area.

Further, the second specific area may be a package on package (PoP) area.

In accordance with a first embodiment of the present invention to achieve the object, there is provided a manufacturing method of a printed circuit board including the steps of: a) coating a first solder resist on an upper surface of a substrate having a circuit pattern formed thereon; b) removing the first solder resist in the remaining portion except a first specific area by performing primary development after exposing the substrate coated with the first solder resist using a first mask of a specific pattern; c) coating a second solder resist, which has different properties from the first solder resist, on the upper surface of the substrate having the first solder resist remaining in the first specific area; and d) removing the second solder resist in the remaining portion except a second specific area by performing secondary development after exposing the substrate coated with the second solder resist using a second mask of a specific pattern.

Here, the manufacturing method of a printed circuit board may further include the step of removing impurities after forming the circuit pattern on the upper surface of the substrate as a pretreatment process before the step a).

Further, preferably, in the step a), the first solder resist may be a liquid type solder resist.

Further, in the step b), the first specific area may be a flip chip area.

Further, preferably, in the step c), the second solder resist may be a solid type solder resist.

Further, in the step d), the second specific area may be a PoP area.

Further, the manufacturing method of a printed circuit board may further include the step of performing curing as a post-treatment process after removing the second solder resist in the remaining portion except the second specific area in the step d).

Further, in accordance with a second embodiment of the present invention to achieve the object, there is provided a manufacturing method of a printed circuit board including the steps of: a) coating a first solder resist on an upper surface of a substrate having a circuit pattern formed thereon; b) primarily exposing the substrate coated with the first solder resist using a first mask of a specific pattern; c) coating a second solder resist, which has different properties from the first solder resist, on the upper surface of the substrate after the primary exposure; and d) removing the first and second solder resists in the remaining portion except first and second specific areas by the first and second masks by performing development after secondarily exposing the substrate coated with the second solder resist using the second mask of a specific pattern.

Here, the manufacturing method of a printed circuit board may further include the step of removing impurities after forming the circuit pattern on the upper surface of the substrate as a pretreatment process before the step a).

Further, preferably, in the step a), the first solder resist may be a liquid type solder resist.

Further, preferably, in the step c), the second solder resist may be a solid type solder resist.

Further, in the step d), the first specific area may be a flip chip area, and the second specific area may be a PoP area.

Further, the manufacturing method of a printed circuit board may further include the step of performing curing as a post-treatment process after removing the first and second solder resists in the step d).

Further, in accordance with a third embodiment of the present invention to achieve the object, there is provided a manufacturing method of a printed circuit board including the steps of: a) coating a solder resist on an upper surface of a substrate having a circuit pattern formed thereon; b) primarily exposing the substrate coated with the solder resist using a first mask of a specific pattern; c) removing a certain portion of the solder resist by primarily developing the primarily exposed substrate using a first developing chemical; d) secondarily exposing the substrate from which the certain portion of the solder resist is removed using a second mask of a specific pattern; and e) removing the solder resist in the remaining area except first and second specific areas by the first and second masks by secondarily developing the secondarily exposed substrate using a second developing chemical.

Here, the manufacturing method of a printed circuit board may further include the step of removing impurities after forming the circuit pattern on the upper surface of the substrate as a pretreatment process before the step a).

Further, in the step c), the first developing chemical may be one of a sodium carbonate (Na₂CO₃) aqueous solution, a potassium carbonate (K₂CO₃) aqueous solution, and a sodium hydroxide (NaOH) aqueous solution.

Further, in the step e), the second developing chemical may be a developing chemical different from the first developing chemical.

At this time, the second developing chemical may be one of a sodium carbonate (Na₂CO₃) aqueous solution, a potassium carbonate (K₂CO₃) aqueous solution, and a sodium hydroxide (NaOH) aqueous solution.

Further, in the step e), the first specific area may be a PoP area, and the second specific area may be a flip chip area.

Further, the manufacturing method of a printed circuit board may further include the step of performing curing as a post-treatment process after removing the solder resist in the step e).

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a structure of a printed circuit board in accordance with an embodiment of the present invention;

FIG. 2 is a flowchart showing an execution process of a manufacturing method of a printed circuit board in accordance with a first embodiment of the present invention;

FIGS. 3a to 3g are views sequentially showing a manufacturing process of the printed circuit board of FIG. 1;

FIG. 4 is a flowchart showing an execution process of a manufacturing method of a printed circuit board in accordance with a second embodiment of the present invention;

FIGS. 5a to 5f are views sequentially showing a process of manufacturing a printed circuit board according to the manufacturing method of a printed circuit board in accordance with the second embodiment of the present invention;

FIG. 6 is a flowchart showing an execution process of a manufacturing method of a printed circuit board in accordance with a third embodiment of the present invention; and

FIGS. 7a to 7f are views sequentially showing a process of manufacturing a printed circuit board according to the manufacturing method of a printed circuit board in accordance with the third embodiment of the present invention.

### DETAILED DESCRIPTION OF THE PREFERABLE EMBODIMENTS

The terms or words used in the present specification and claims should not be interpreted as being limited to typical or dictionary meanings, but should be interpreted as having meanings and concepts relevant to the technical spirit of the present invention based on the rule according to which an inventor can appropriately define the concept of the term to describe his/her own invention in the best manner.

Throughout the specification, when an element is referred to as “including” another element, it can further include the other element rather than exclude the other element unless the context clearly indicates otherwise. Further, the terms “unit”, “module”, “apparatus”, etc. used in the present specification represent a unit for processing at least one function or operation and may be implemented by hardware, software, or a combination thereof.

Hereinafter, embodiments of the present invention will be described in detail with reference to the accompanying drawings.

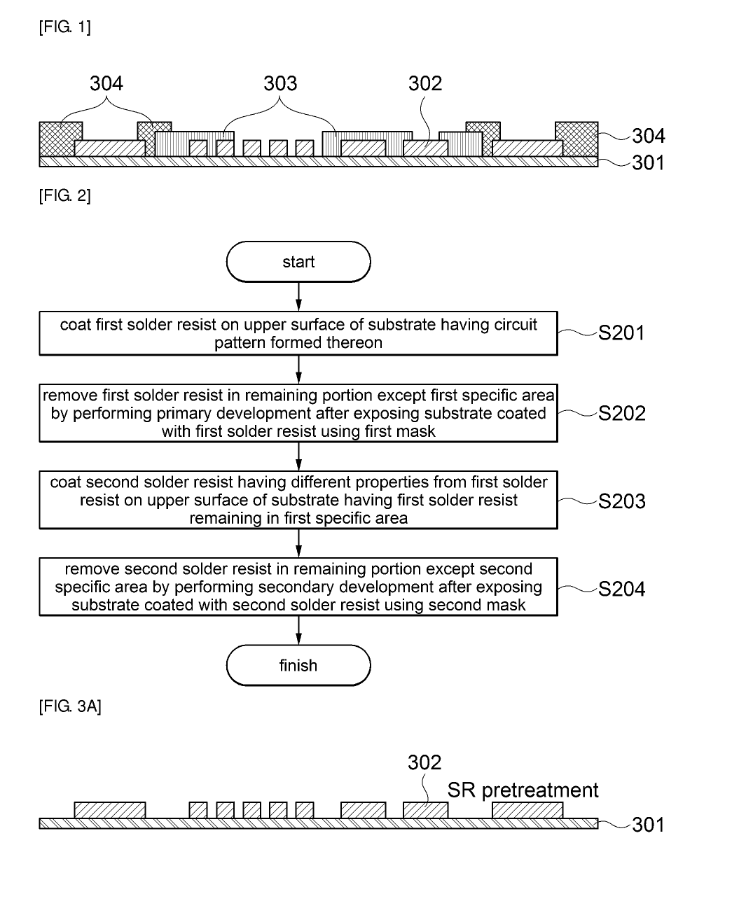

FIG. 1 is a view showing a structure of a printed circuit board in accordance with an embodiment of the present invention.

Referring to FIG. 1, a printed circuit board in accordance with the present invention includes a substrate 301, a circuit pattern 302, a first solder resist 303, and a second solder resist 304.

The substrate 301 forms a base of the printed circuit board 300. The substrate 301 may have a single-layered structure or a multi-layered structure. Further, a circuit or a via may be formed inside a body of the substrate 301 or an electronic component may be embedded in the body of the substrate 301.

The circuit pattern 302 is formed on the substrate 301 in a predetermined pattern. The circuit pattern 302 may be formed by photolithography using a mask of a predetermined pattern for forming a circuit pattern after coating one surface (or both surfaces) of the substrate 301 with a conductive material (for example, Cu).

The first solder resist 303 is formed in a first specific area of the substrate 301 on which the circuit pattern 302 is formed. Here, the first specific area may be a flip chip area. This will be described again below.

The second solder resist 304 is formed in a second specific area of the substrate 301 on which the circuit pattern 302 is formed to be stepped from the first solder resist 303 and has different properties from the first solder resist 303. Here, the second specific area may be a package on package (PoP) area. This will be described again below.

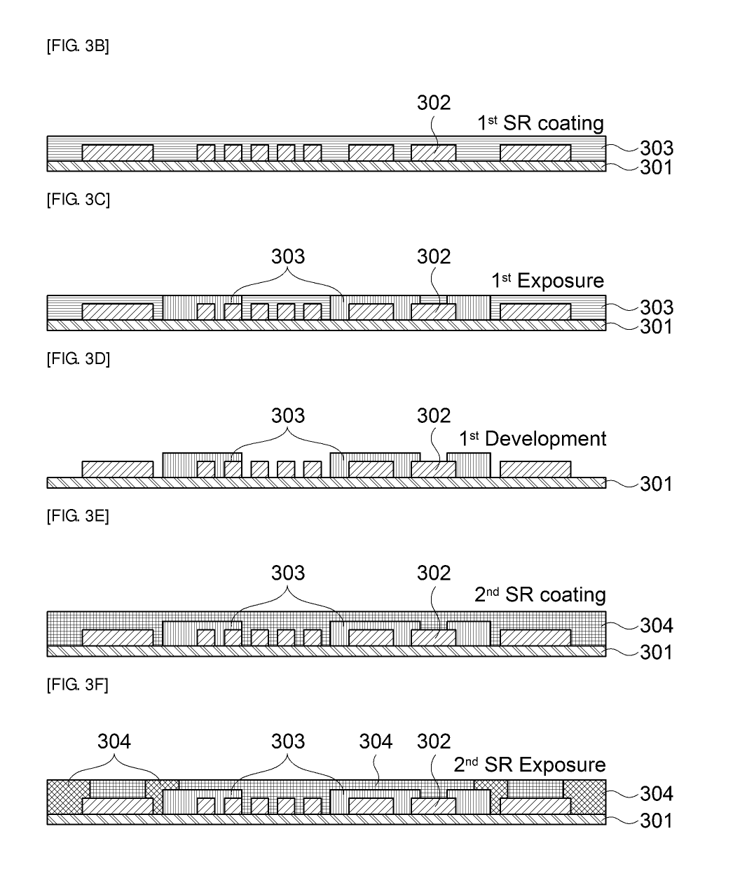

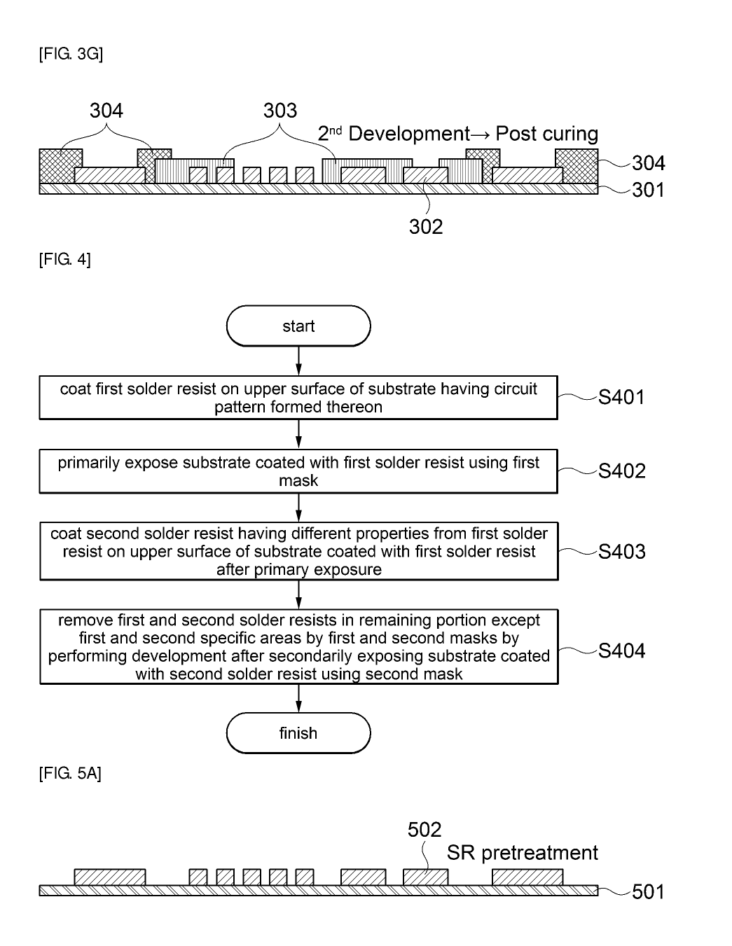

FIG. 2 and FIGS. 3a to 3g show a manufacturing process of the printed circuit board according to the present invention having the above structure, wherein FIG. 2 is a flowchart showing an execution process of a manufacturing method of a printed circuit board in accordance with a first embodiment of the present invention, and FIGS. 3a to 3g are views sequentially showing a manufacturing process of the printed circuit board of FIG. 1.

Referring to FIG. 2 and FIGS. 3a to 3g, according to the manufacturing method of a printed circuit board in accordance with the first embodiment of the present invention, first, a first solder resist 303 is coated on an upper surface of a substrate 301 having a circuit pattern 302 formed thereon (S201, refer to FIG. 3b). Here, preferably, the first solder resist 303 is a liquid type solder resist. This is to comprehensively consider process capability characteristics, reliability characteristics, etc. in relation to the fact that the thickness of the finally remaining first solder resist 303 is relatively smaller than the thickness of a second solder resist 304 described later.

Further, preferably, the step of removing impurities after forming the circuit pattern 302 on the upper surface of the substrate 301 as a pretreatment process may be further included before the above step S201.

When the coating of the first solder resist 303 is completed by the above, the first solder resist 303 in the remaining portion except a first specific area is removed by performing primary development after exposing the substrate 301 coated with the first solder resist 303 using a first mask (not shown) of a specific pattern (S202, refer to FIGS. 3c and 3d). Here, the first specific area may be a flip chip area. That is, the first specific area, where a flip chip is to be mounted, is a portion in which the first solder resist 303 is left through the developing process after exposure.

When the removal of the first solder resist 303 in the remaining portion except the first specific area is completed in this way, the second solder resist 304 having different properties from the first solder resist 303 is coated on the upper surface of the substrate 301 having the first solder resist 303 remaining in the first specific area (S203, refer to FIG. 3e). Here, preferably, the second solder resist 304 is a solid type solder resist. This is to comprehensively consider process capability characteristics, reliability characteristics, etc. in relation to the fact that the thickness of the finally remaining second solder resist 304 is relatively larger than the thickness of the first solder resist 303 as described above.

When the coating of the second solder resist 304 is completed, the second solder resist 304 in the remaining portion except a second specific area is removed by performing secondary development after exposing the substrate 301 coated with the second solder resist 304 using a second mask (not shown) of a specific pattern (S204, refer to FIGS. 3f and 3g). Here, the second specific area may be a PoP area. That is, the second specific area, where another package is stacked on one package including the printed circuit board of the present invention, is a portion in which the second solder resist 304 is left through the developing process after exposure.

Here, further, preferably, the step of performing curing as a post-treatment process after removing the second solder resist 304 in the remaining portion except the second specific area may be further included (refer to FIG. 3g).

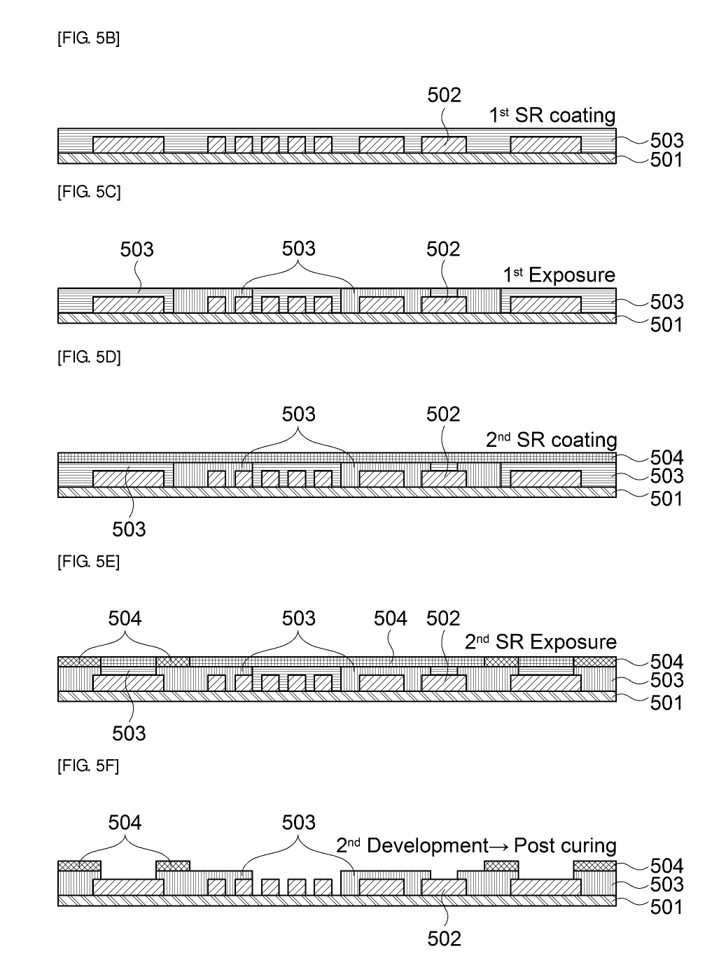

FIG. 4 is a flowchart showing an execution process of a manufacturing method of a printed circuit board in accordance with a second embodiment of the present invention, and FIGS. 5a to 5f are views sequentially showing a process of manufacturing a printed circuit board according to the manufacturing method of a printed circuit board in accordance with the second embodiment of the present invention.

Referring to FIG. 4 and FIGS. 5a to 5f, according to the manufacturing method of a printed circuit board in accordance with the second embodiment of the present invention, first, a first solder resist 503 is coated on an upper surface of a substrate 501 having a circuit pattern 502 formed thereon (S401, refer to FIG. 5b). Here, the step of removing impurities after forming the circuit pattern 502 on the upper surface of the substrate 501 as a pretreatment process may be further included before the step S401.

Further, preferably, the first solder resist 503 is a liquid type solder resist. As described above, this is to comprehensively consider process capability characteristics, reliability characteristics, etc. in relation to the fact that the thickness of the finally remaining first solder resist 503 is relatively smaller than the thickness of a second solder resist 504 described later.

When the coating of the first solder resist 503 is completed by the above, the substrate 501 coated with the first solder resist 503 is primarily exposed using a first mask (not shown) of a specific pattern (S402, refer to FIG. 5c).

And, after the primary exposure, the second solder resist 504 having different properties from the first solder resist 503 is coated on the upper surface of the substrate 501 coated with the first solder resist 503 (S403, refer to FIG. 5d). Here, preferably, the second solder resist 504 is a solid type solder resist. This is also to comprehensively consider process capability characteristics, reliability characteristics, etc. in relation to the fact that the thickness of the finally remaining second solder resist 504 is relatively smaller than the thickness of the first solder resist 503 as described above.

When the coating of the second solder resist 504 is completed like this, the substrate 501 coated with the second solder resist 504 is developed after being secondarily exposed using a second mask (not shown) of a specific pattern to remove the first and second solder resists 503 and 504 in the remaining portion except first and second specific areas by the first and second masks (S404, refer to FIGS. 5e and 5f). Here, the first specific area may be a flip chip area, and the second specific area may be a PoP area.

Here, further, preferably, the step of performing curing as a post-treatment process after removing the first and second solder resists 503 and 504 may be further included (refer to FIG. 5f).

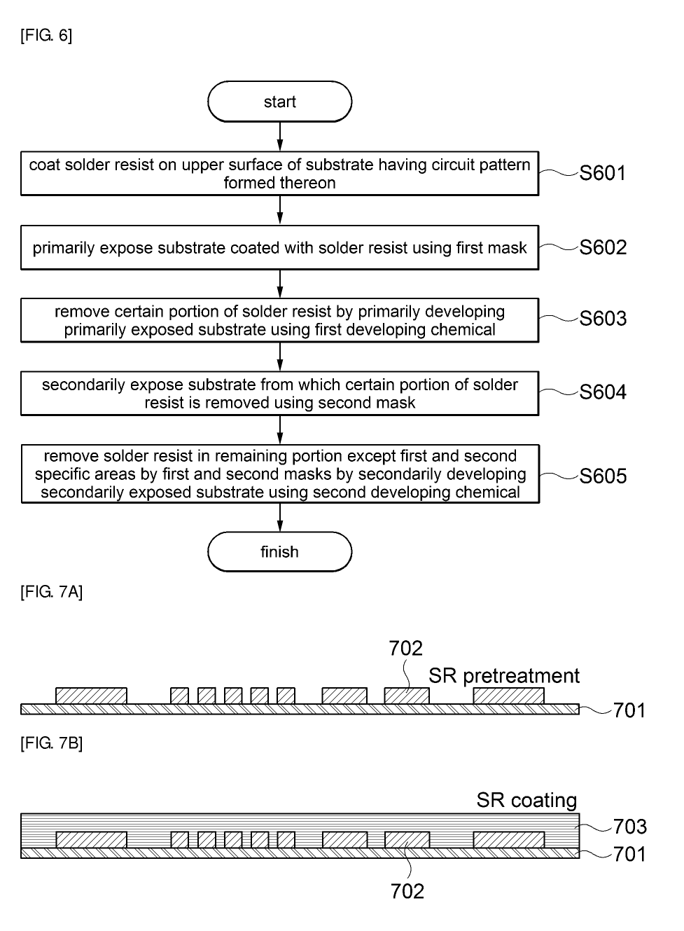

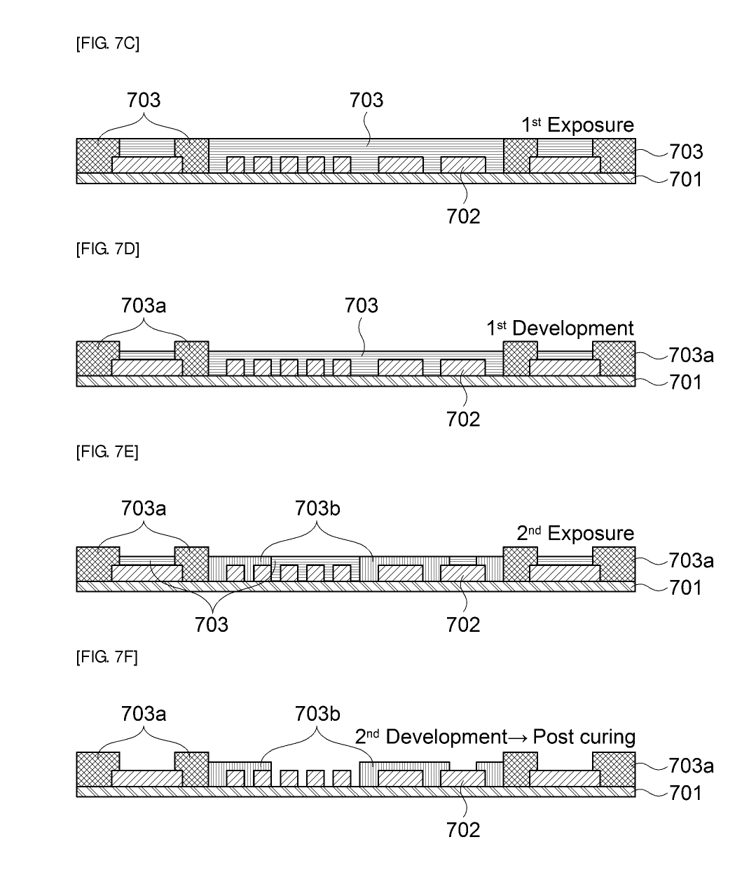

Meanwhile, FIGS. 6 and 7 show a manufacturing method of a printed circuit board in accordance with a third embodiment of the present invention, wherein FIG. 6 is a flowchart showing an execution process of the manufacturing method of a printed circuit board in accordance with the third embodiment of the present invention, and FIGS. 7a to 7f are views sequentially showing a process of manufacturing a printed circuit board according to the manufacturing method of a printed circuit board in accordance with the third embodiment of the present invention.

Referring to FIG. 6 and FIGS. 7a to 7f, according to the manufacturing method of a printed circuit board in accordance with the third embodiment of the present invention, first, a solder resist 703 is coated on an upper surface of a substrate 701 having a circuit pattern 702 formed thereon (S601, refer to FIG. 7b). Here, preferably, the step of removing impurities after forming the circuit pattern 702 on the upper surface of the substrate 701 as a pretreatment process may be further included before the step S601.

When the coating of the solder resist 703 is completed as above, the substrate 701 coated with the solder resist 703 is primarily exposed using a first mask (not shown) of a specific pattern (S602, refer to FIG. 7c).

After that, a certain portion of the solder resist 703 is removed by primarily developing the primarily exposed substrate 701 using a first developing chemical (S603, refer to FIG. 7d). That is, the solder resist in a first specific area (PoP area) 703a described below doesn't show a photoreaction by the primary exposure using the first mask (not shown) of a specific pattern in the step S602. Thus, the first specific area 703a is left while remaining a minimum height (thickness) without being removed by the primary development using the first developing chemical. And the properties of the solder resist in the remaining portion (that is, the portion from which the certain portion of the solder resist is removed) except the first specific area 703a are changed by the first developing chemical. Here, the first developing chemical may be one of a sodium carbonate (Na₂CO₃) aqueous solution, a potassium carbonate (K₂CO₃) aqueous solution, and a sodium hydroxide (NaOH) aqueous solution.

After that, the substrate 701, from which the certain portion of the solder resist 703 is removed, is secondarily exposed using a second mask (not shown) of a specific pattern (S604, refer to FIG. 7e).

Then, the solder resist 703 in the remaining area except the first and second specific areas by the first and second masks is removed by secondarily developing the secondarily exposed substrate 701 using a second developing chemical (S605, refer to 7f). Here, the first specific area may be a PoP area, and the second specific area may be a flip chip area.

Further, the second developing chemical is a developing chemical different from the first developing chemical. At this time, the second developing chemical may be one of a sodium carbonate (Na₂CO₃) aqueous solution, a potassium carbonate (K₂CO₃) aqueous solution, and a sodium hydroxide (NaOH) aqueous solution. That is, when the first developing chemical is a sodium carbonate (Na₂CO₃) aqueous solution, the second developing chemical may be a potassium carbonate (K₂CO₃) aqueous solution or a sodium hydroxide (NaOH) aqueous solution. Further, when the first developing chemical is a potassium carbonate (K₂CO₃) aqueous solution, the second developing chemical may be a sodium carbonate (Na₂CO₃) aqueous solution or a sodium hydroxide (NaOH) aqueous solution. Further, when the first developing chemical is a sodium hydroxide (NaOH) aqueous solution, the second developing chemical may be a sodium carbonate (Na₂CO₃) aqueous solution or a potassium carbonate (K₂CO₃) aqueous solution. Like this, in the manufacturing method of a printed circuit board according to the third embodiment of the present invention, in developing the solder resist after the primary and secondary exposure, different developing chemicals are used in the respective development steps. By using the different developing chemicals in the respective development steps like this, the properties of the solder resist 703a remaining in the first specific area after the primary development are different from those of the solder resist 703b remaining in the second specific area after the secondary development.

Meanwhile, preferably, the step of performing curing as a post-treatment process after removing the solder resist 703 in the step S605 may be further included (refer to FIG. 7f).

As in the above description, the printed circuit board and the manufacturing method thereof according to the present invention can differentiate the properties of the thin solder resist area and the thick solder resist area by coating the first and second solder resists having different properties two times and performing the primary and secondary development, thereby improving reliability of PCB products by reducing defects such as lifting of the relatively thin solder resist area.

According to the present invention as above, the thin solder resist area and the thick solder resist area can have different properties by coating the first and second solder resists having different properties two times and performing the primary and secondary development. Thus, it is possible to improve reliability of PCB products by reducing defects such as lifting of the relatively thin solder resist area.

Although the preferable embodiments of the present invention have been described in detail above, the present invention is not limited to the embodiments and it will be appreciated by those skilled in the art that various modifications and applications may be made in the embodiments without departing from the technical spirit of the present invention. Therefore, the range of protection of the present invention should be interpreted from the appended claims and all technical sprits within the range equivalent to the range should be interpreted as being included in the range of the rights of the present invention.

1. A printed circuit board comprising:
a substrate for forming a base of the printed circuit board;
a circuit pattern formed on the substrate in a predetermined pattern;
a first solder resist formed in a first specific area on the substrate having the circuit pattern formed thereon; and
a second solder resist formed in a second specific area on the substrate having the circuit pattern formed thereon to be stepped from the first solder resist and having different properties from the first solder resist.

2. The printed circuit board according to claim 1, wherein the first specific area is a flip chip area.

3. The printed circuit board according to claim 1, wherein the second specific area is a package on package (PoP) area.

4. A manufacturing method of a printed circuit board, comprising:
coating a first solder resist on an upper surface of a substrate having a circuit pattern formed thereon;
removing the first solder resist in the remaining portion except a first specific area by performing primary development after exposing the substrate coated with the first solder resist using a first mask of a specific pattern;
coating a second solder resist, which has different properties from the first solder resist, on the upper surface of the substrate having the first solder resist remaining in the first specific area; and
removing the second solder resist in the remaining portion except a second specific area by performing secondary development after exposing the substrate coated with the second solder resist using a second mask of a specific pattern.

5. The manufacturing method of a printed circuit board according to claim 4, further comprising, before the coating a first solder resist, removing impurities after forming the circuit pattern on the upper surface of the substrate as a pretreatment process.

6. The manufacturing method of a printed circuit board according to claim 4, wherein in the coating a first solder resist, the first solder resist is a liquid type solder resist.

7. The manufacturing method of a printed circuit board according to claim 4, wherein in the removing the first solder resist, the first specific area is a flip chip area.

8. The manufacturing method of a printed circuit board according to claim 4, wherein in the coating a second solder resist, the second solder resist is a solid type solder resist.

9. The manufacturing method of a printed circuit board according to claim 4, wherein in the removing the second solder resist, the second specific area is a PoP area.

10. The manufacturing method of a printed circuit board according to claim 4, further comprising:
performing curing as a post-treatment process after removing the second solder resist in the remaining portion except the second specific area in the removing the second solder resist.

11. A manufacturing method of a printed circuit board, comprising:
coating a first solder resist on an upper surface of a substrate having a circuit pattern formed thereon;
primarily exposing the substrate coated with the first solder resist using a first mask of a specific pattern;
coating a second solder resist, which has different properties from the first solder resist, on the upper surface of the substrate after the primary exposure; and
removing the first and second solder resists in the remaining portion except first and second specific areas by the first and second masks by performing development after secondarily exposing the substrate coated with the second solder resist using the second mask of a specific pattern.

12. The manufacturing method of a printed circuit board according to claim 11, further comprising, before the coating a first solder resist, removing impurities after forming the circuit pattern on the upper surface of the substrate as a pretreatment process.

13. The manufacturing method of a printed circuit board according to claim 11, wherein in the coating a first solder resist, the first solder resist is a liquid type solder resist.

14. The manufacturing method of a printed circuit board according to claim 11, wherein in the coating a second solder resist, the second solder resist is a solid type solder resist.

15. The manufacturing method of a printed circuit board according to claim 11, wherein in the removing the first and second solder resists, the first specific area is a flip chip area and the second specific area is a PoP area.

16. The manufacturing method of a printed circuit board according to claim 15, wherein the second solder resist is stacked on the first solder resist in the area where the first specific area and the second specific area are overlapped with each other.

17. The manufacturing method of a printed circuit board according to claim 11, further comprising:
performing curing as a post-treatment process after removing the first and second solder resists in the removing the first and second solder resists.

18. A manufacturing method of a printed circuit board, comprising:
coating a solder resist on an upper surface of a substrate having a circuit pattern formed thereon;
primarily exposing the substrate coated with the solder resist using a first mask of a specific pattern;
removing a certain portion of the solder resist by primarily developing the primarily exposed substrate using a first developing chemical;
secondarily exposing the substrate from which the certain portion of the solder resist is removed using a second mask of a specific pattern; and
removing the solder resist in the remaining area except first and second specific areas by the first and second masks by secondarily developing the secondarily exposed substrate using a second developing chemical.

19. The manufacturing method of a printed circuit board according to claim 18, further comprising, before the coating, removing impurities after forming the circuit pattern on the upper surface of the substrate as a pretreatment process.

20. The manufacturing method of a printed circuit board according to claim 18, wherein in the removing a certain portion of the solder resist, the first developing chemical is one of a sodium carbonate (Na₂CO₃) aqueous solution, a potassium carbonate (K₂CO₃) aqueous solution, and a sodium hydroxide (NaOH) aqueous solution.

21. The manufacturing method of a printed circuit board according to claim 18, wherein in the removing the solder resist in the remaining area, the second developing chemical is one of a sodium carbonate (Na₂CO₃) aqueous solution, a potassium carbonate (K₂CO₃) aqueous solution, and a sodium hydroxide (NaOH) aqueous solution.

22. The manufacturing method of a printed circuit board according to claim 18, wherein in the removing the solder resist in the remaining area, the first specific area is a PoP area and the second specific area is a flip chip area.

23. The manufacturing method of a printed circuit board according to claim 18, further comprising:
performing curing as a post-treatment process after removing the solder resist in the removing the solder resist in the remaining area.
